(19) United States
(12) Patent Application Publication
(10) Pub. No.: US 2022/0052302 A1
(43) Pub. Date: Feb. 17, 2022

(54) MANUFACTURING METHOD OF FLEXIBLE DISPLAY PANEL

(71) Applicant: Shenzhen China Star Optoelectronics Semiconductor Display Technology Co., Ltd., Shenzhen, Guangdong (CN)

(72) Inventor: Zhiping HU, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/252,825

(22) PCT Filed: Apr. 9, 2020
(86) PCT No.: PCT/CN2020/083849

§ 371 Date: Dec. 16, 2020

(30) Foreign Application Priority Data
Mar. 20, 2020 (CN) 202010202517.4

(51) Int. Cl. H01L 51/56; H01L 51/50; H01L 27/32; H01L 27/15; H01L 51/52

(52) U.S. Cl. CPC H01L 51/56; H01L 51/502; H01L 51/0097; H01L 27/156; H01L 51/5206; H01L 27/3211

(57) ABSTRACT

A manufacturing method of a flexible display panel is provided, which includes: providing a flexible substrate; forming a pixel barrier wall on the flexible substrate, wherein the pixel barrier wall is formed around a pixel opening; and forming an anode, a hole injection layer, a hole transport layer, and a perovskite quantum dot light-emitting layer in the pixel opening by inkjet printing sequentially.

### BACKGROUND OF INVENTION

### Field of Invention

The present application relates to the field of display panel manufacturing technology, and particularly to a manufacturing method of a flexible display panel.

### Description of Prior Art

Flexible display panels are bendable and deformable display panels made of flexible materials. The flexible display panels have advantages of low power consumption, small size, lightweight, ease of assembly, ease of transport, diversified display modes, outstanding display quality and so on. The flexible display panels have been mainly applied to portable electronic devices and touch sensitive devices and so on. The flexible display panels have wide development prospects.

At present, as a mainstream technology in the flexible display field, organic light emitting diodes (OLEDs) have advantages of active light-emission and superseding need for a backlight. Compared with OLEDs, quantum dot light-emitting diodes (QLEDs) are also active light-emitting devices and have advantages of better stability and wider color gamut, and can be easily made into bendable and foldable flexible display panels.

A perovskite material is a novel light-emitting material with advantages of being ease of synthesis, size adjustability, band gap adjustability, high carrier mobility ratio, high light-emitting efficiency, narrow full width at half maximum, wide color gamut, and so on. At present, an external quantum efficiency of QLEDs based on the perovskite material has already exceeded 20%, and the perovskite material has become a potential material of new generation display luminescence technology. Due to its outstanding photoelectric properties, the perovskite material has been applied to display luminescence devices. However, manufacturing large-area flexible QLEDs based on the perovskite material is difficult in that it is hard to pattern the perovskite material. Therefore, an effective manufacturing method of a flexible QLED display panels based on the perovskite material is needed.

### SUMMARY OF INVENTION

The present application provides a manufacturing method of a flexible display panel, an anode, a hole injection layer, a hole transport layer, and a perovskite quantum dot light-emitting layer of the flexible display panel are all formed by inkjet printing, so that the flexible QLED display panels can have better bending performance based on the perovskite material.

The present application provides a manufacturing method of a flexible display panel, comprising following steps:

providing a flexible substrate;

forming a pixel barrier wall on the flexible substrate, wherein the pixel barrier wall is formed around a pixel opening; and

forming an anode, a hole injection layer, a hole transport layer, and a perovskite quantum dot light-emitting layer successively in the pixel opening by inkjet printing.

In the manufacturing method of a flexible display panel provided in the embodiments of the present application, forming the pixel barrier wall on the flexible substrate comprises following steps:

covering a photoresist layer on the flexible substrate; and

patterning the photoresist layer to form the pixel barrier wall.

In the manufacturing method of a flexible display panel provided in the embodiments of the present application, further comprising following steps:

forming an electron transport layer and an electron injection layer on the perovskite quantum dot light-emitting layer successively by inkjet printing.

In the manufacturing method of a flexible display panel provided in the embodiments of the present application, further comprising following steps:

forming a cathode on a side of the electron injection layer away from the anode by vapor deposition.

In the manufacturing method of a flexible display panel provided in the embodiments of the present application, further comprising following steps:

forming an electron transport layer and an electron injection layer on the perovskite quantum dot light-emitting layer successively by vapor deposition.

In the manufacturing method of a flexible display panel provided in the embodiments of the present application, further comprising following steps:

forming a cathode on a side of the electron injection layer away from the anode by vapor deposition.

In the manufacturing method of a flexible display panel provided in the embodiments of the present application, a material of the anode comprises any one of a nano-gold, a nano-silver, or a carbon electrode.

In the manufacturing method of a flexible display panel provided in the embodiments of the present application, a material of the perovskite quantum dot light-emitting layer comprises any one of an organic-inorganic-hybridized perovskite material or an inorganic perovskite material.

In the manufacturing method of a flexible display panel provided in the embodiments of the present application, the perovskite quantum dot light-emitting layer comprises any one of a red perovskite quantum dot light-emitting layer, a green perovskite quantum dot light-emitting layer, or a blue perovskite quantum dot light-emitting layer.

In the manufacturing method of a flexible display panel provided in the embodiments of the present application, the pixel opening comprises a red sub-pixel opening, a green sub-pixel opening, and a blue sub-pixel opening;

the perovskite quantum dot light-emitting layer in the red sub-pixel opening is the red perovskite quantum dot light-emitting layer, the perovskite quantum dot light-emitting layer in the green sub-pixel opening is the green perovskite quantum dot light-emitting layer, and the perovskite quantum dot light-emitting layer in the blue sub-pixel opening is the blue perovskite quantum dot light-emitting layer.

In the manufacturing method of a flexible display panel provided in the embodiments of the present application, a material of the flexible substrate comprises any one or more of polyimide, polypropylene, and polyvinyl chloride.

In the manufacturing method of a flexible display panel provided in the embodiments of the present application, a material of the pixel barrier wall comprises a black color resist material.

The present application also provides a manufacturing method of a flexible display panel, comprising following steps:

providing a flexible substrate;

forming a pixel barrier wall on the flexible substrate, wherein the pixel barrier wall is formed around a pixel opening;

forming an anode, a hole injection layer, a hole transport layer, a perovskite quantum dot light-emitting layer, an electron transport layer, and an electron injection layer successively in the pixel opening by inkjet printing; and

forming a cathode on a side of the electron injection layer away from the anode by vapor deposition.

In the manufacturing method of a flexible display panel provided in the embodiments of the present application, forming the pixel barrier wall on the flexible substrate comprises following steps:

covering a photoresist layer on the flexible substrate; and

patterning the photoresist layer to form the pixel barrier wall.

In the manufacturing method of a flexible display panel provided in the embodiments of the present application, a material of the anode comprises any one of a nano-gold, a nano-silver, or a carbon electrode.

In the manufacturing method of a flexible display panel provided in the embodiments of the present application, a material of the perovskite quantum dot light-emitting layer comprises any one of an organic-inorganic-hybridized perovskite material or an inorganic perovskite material.

In the manufacturing method of a flexible display panel provided in the embodiments of the present application, the perovskite quantum dot light-emitting layer comprises any one of a red perovskite quantum dot light-emitting layer, a green perovskite quantum dot light-emitting layer, or a blue perovskite quantum dot light-emitting layer.

In the manufacturing method of a flexible display panel provided in the embodiments of the present application, the pixel opening comprises a red sub-pixel opening, a green sub-pixel opening, and a blue sub-pixel opening;

the perovskite quantum dot light-emitting layer in the red sub-pixel opening is the red perovskite quantum dot light-emitting layer, the perovskite quantum dot light-emitting layer in the green sub-pixel opening is the green perovskite quantum dot light-emitting layer, and the perovskite quantum dot light-emitting layer in the blue sub-pixel opening is the blue perovskite quantum dot light-emitting layer.

In the manufacturing method of a flexible display panel provided in the embodiments of the present application, a material of the flexible substrate comprises any one or more of polyimide, polypropylene, and polyvinyl chloride.

In the manufacturing method of a flexible display panel provided in the embodiments of the present application, a material of the pixel barrier wall comprises a black color resist material.

Compared with the prior art, in the manufacturing method of a flexible display panel provided in embodiments of the present application, an anode, a hole injection layer, a hole transport layer, and a perovskite quantum dot light-emitting layer are all formed by inkjet printing, a patterning process for the perovskite quantum dot light-emitting layer is eliminated, the difficulty of a manufacture process is reduced and a mask process therein is saved, a manufacture cost and a raw materials cost are reduced, a manufacture efficiency is increased; and, as the anode is formed in the pixel opening by inkjet printing, an etching process for forming the patterned anode is eliminated, a mask process is further saved, the difficulty of the manufacture process is further reduced, the manufacture material cost and the raw materials cost is further reduced, and the manufacture efficiency is further increased; in addition, the anode formed is flexible, which can enhance a bending performance of a flexible QLED display panel better.

### BRIEF DESCRIPTION OF DRAWINGS

FIG. 1 is a flow chart of a manufacturing method of a flexible display panel provided in the embodiments of the present application.

FIG. 2 is a structural schematic diagram of a flexible substrate and a pixel barrier wall provided in the embodiments of the present application.

FIG. 3 is a structural schematic diagram of cross section of partial flexible display panel provided in the embodiments of the present application.

### DETAILED DESCRIPTION OF PREFERRED EMBODIMENTS

The present application will describe hereinafter the technical solution of the embodiments with figures of the embodiments clearly and completely. What is described hereinafter is only a part of, but not all of, the embodiments of the present application. Based on the embodiments provided in the present application, other embodiments achieved by those skilled in the art without creative work are within the protection scope of the present application.

An exemplified manufacturing method of a QLED display panel comprises: forming a perovskite quantum dot light-emitting layer by vapor deposition, patterning the perovskite quantum dot light-emitting layer, and disposing other functional layers on the perovskite quantum dot light-emitting layer to constitute a patterned QLED device. However, patterning the perovskite quantum dot light-emitting layer is hard to fulfill. Therefore the present application provides an effective manufacturing method of a flexible display panel based on the perovskite material.

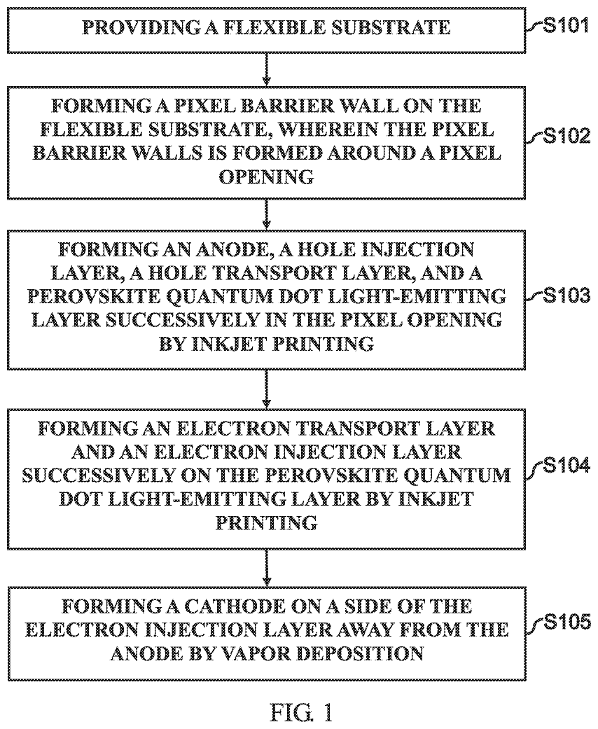

Specifically, as shown in FIG. 1, the embodiments of the present application provide a manufacturing method of a flexible display panel, comprising following steps:

Step S101: providing a flexible substrate.

Specifically, the flexible substrate is transparent, and a material of the flexible substrate comprises any one or more of polyimide, polypropylene, and polyvinyl chloride.

Step S102: forming a pixel barrier wall on the flexible substrate, wherein the pixel barrier wall is formed around a pixel opening.

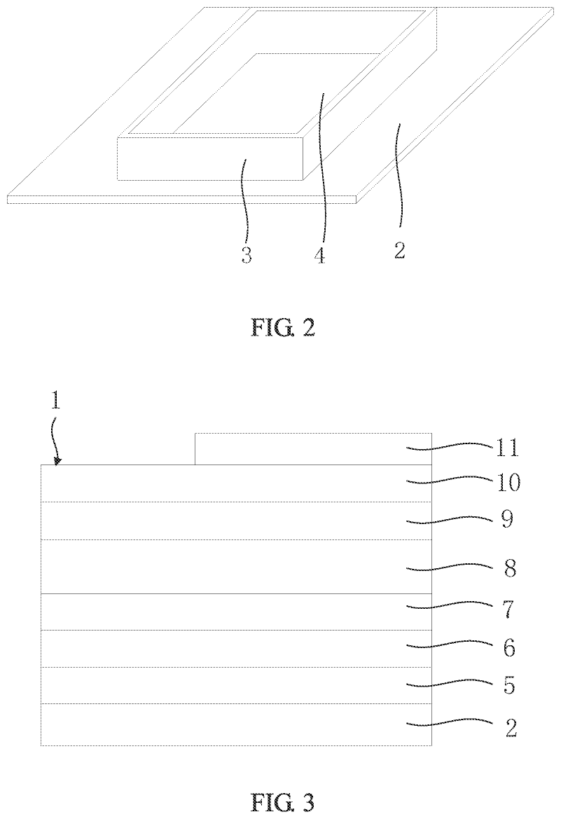

Specifically, as shown in FIG. 2, the pixel barrier wall 3 is formed around a pixel opening 4 on the flexible substrate 2, a shape of the pixel opening 4 can be either rectangular or other shapes, which is not limited herein.

Specifically, forming the pixel barrier wall on the flexible substrate comprises following steps:

covering a photoresist layer on the flexible substrate;

patterning the photoresist layer to form the pixel barrier wall.

Specifically, a material of the photoresist layer comprises a black color resist material, that is, a material of the pixel barrier wall comprises the black color resist material. The photoresist layer can be patterned according to a predetermined shape of the pixel opening.

Step S103: forming an anode, a hole injection layer, a hole transport layer, and a perovskite quantum dot light-emitting layer successively in the pixel opening by inkjet printing.

Specifically, a material of the anode comprises any one of a nano-gold, a nano-silver, or a carbon electrode; a material of the perovskite quantum dot light-emitting layer comprises either an organic-inorganic-hybridized perovskite material or an inorganic perovskite material. The perovskite quantum dot light-emitting layer comprises any one of a red perovskite quantum dot light-emitting layer, a green perovskite quantum dot light-emitting layer, or a blue perovskite quantum dot light-emitting layer.

Specifically, the anode is formed by inkjet printing in the pixel opening surrounded by the pixel barrier wall. As inkjet printing belongs to a liquid method, during a process of forming the anode by inkjet printing, an ink material of the anode flows and covers the pixel opening completely and then forms a patterned anode directly, an etching process for forming the patterned anode is eliminated, and saving a mask process. The difficulty and cost of a manufacturing process are thus reduced, and since a cover area of the anode is equivalent to an area of the pixel opening, the material of the anode can be conserved, the material waste caused by etching is eliminated, and thus the cost of raw materials is reduced; the material of the anode comprises any one of a nano-gold, a nano-silver, or a carbon electrode, so that the anode formed has better flexibility, and the bending performance of the display panel is improved. In addition, other functional layers on the anode are also formed by inkjet printing, ink materials of the functional layers cover the whole pixel opening during processes of forming each layer by inkjet printing, so that any two adjacent layers are completely in contact, and a stability of electrical connection is ensured.

Specifically, the perovskite quantum dot light-emitting layer is also formed by inkjet printing in the pixel opening surrounded by the pixel barrier wall. As the inkjet printing belongs to a liquid method, during a process of forming the perovskite quantum dot light-emitting layer by inkjet printing, an ink material of perovskite quantum dot light-emitting layer flows and covers the pixel opening completely and then forms a patterned perovskite quantum dot light-emitting layer directly, an etching process for forming the patterned perovskite quantum dot light-emitting layer is eliminated, and a mask process is saved, reducing the difficulty and cost of the manufacturing process, and since a cover area of the perovskite quantum dot light-emitting layer is equivalent to the area of the pixel opening, saving the material of perovskite quantum dot light-emitting layer, eliminating material waste caused by etching, and reducing the cost of raw materials.

Step S104: forming an electron transport layer and an electron injection layer successively on the perovskite quantum dot light-emitting layer by inkjet printing.

Specifically, the electron transport layer and the electron injection layer can also be formed on the perovskite quantum dot light-emitting layer by vapor deposition.

Step S105: forming a cathode on a side of the electron injection layer away from the anode by vapor deposition method.

Specifically, as shown in FIG. 3, the anode 5, the hole injection layer 6, the hole transport layer 7, the perovskite quantum dot light-emitting layer 8, the electron transport layer 9, the electron injection layer 10, and the cathode 11 are successively formed on the flexible substrate.

In one embodiment, the pixel openings 4 comprise a red sub-pixel opening, a green sub-pixel opening, and a blue sub-pixel opening. The perovskite quantum dot light-emitting layer in a red sub-pixel opening is a red perovskite quantum dot light-emitting layer, the perovskite quantum dot light-emitting layer in a green sub-pixel opening is a green perovskite quantum dot light-emitting layer, and the perovskite quantum dot light-emitting layer in a blue sub-pixel opening is a blue perovskite quantum dot light-emitting layer.

Specifically, the anode, the hole injection layer, the hole transport layer, the red perovskite quantum dot light-emitting layer, the electron transport layer, the electron injection layer, and the cathode in the red sub-pixel opening constitute a red QLED device configured to emit red light; the anode, the hole injection layer, the hole transport layer, the green perovskite quantum dot light-emitting layer, the electron transport layer, the electron injection layer, and the cathode in the green sub-pixel opening constitute a green QLED device configured to emit green light; the anode, the hole injection layer, the hole transport layer, the blue perovskite quantum dot light-emitting layer, the electron transport layer, the electron injection layer, and the cathode in the blue sub-pixel opening constitute a blue QLED device configured to emit blue light.

Specifically, a display panel configured to display full color comprises a plurality of red, green, and blue QLED devices.

In the present embodiment, as the anode, the hole injection layer, the hole transport layer, the perovskite quantum dot light-emitting layer, the electron transport layer, and the electron injection layer in each QLED device are all formed by inkjet printing, a patterning process and a mask process for the perovskite quantum dot light-emitting layer are eliminated, the difficulty and cost of the manufacturing process are reduced, reducing the cost of raw materials, and increasing manufacturing efficiency; and as the anode is formed in the pixel opening by inkjet printing, an etching process for forming the patterned anode is eliminated, and a mask process is further saved, therefore the difficulty and cost of the manufacturing process are further reduced, the cost of raw materials is further reduced, and the manufacturing efficiency is further increased; in addition, as the anode formed is flexible, therefore creating a flexible QLED display panel with even better bending performance.

A manufacturing method of a flexible display panel provided in the embodiments of the present application is described in detail, the principle of the present application and the embodiments are described with examples in this specification, and the description of the aforementioned embodiments is intended only to assist in understanding of the technical solution and its core ideas in this application. Those skilled in the art shall understand that they can either make changes or replacements for part of the characteristics based on the technical solution provided in the aforementioned embodiments, and such changes and replacements are still within the scope of the embodiments of the present application.

What is claimed is:

1. A manufacturing method of a flexible display panel, comprising following steps:
providing a flexible substrate;
forming a pixel barrier wall on the flexible substrate, wherein the pixel barrier wall is formed around a pixel opening; and
forming an anode, a hole injection layer, a hole transport layer, and a perovskite quantum dot light-emitting layer successively in the pixel opening by inkjet printing.

2. The manufacturing method of claim 1, wherein forming the pixel barrier wall on the flexible substrate comprises following steps:
covering a photoresist layer on the flexible substrate; and
patterning the photoresist layer to form the pixel barrier wall.

3. The manufacturing method of claim 1, further comprising following steps:
forming an electron transport layer and an electron injection layer on the perovskite quantum dot light-emitting layer successively by inkjet printing.

4. The manufacturing method of claim 3, further comprising following steps:
forming a cathode on a side of the electron injection layer away from the anode by vapor deposition.

5. The manufacturing method of claim 1, further comprising following steps:
forming an electron transport layer and an electron injection layer on the perovskite quantum dot light-emitting layer successively by vapor deposition.

6. The manufacturing method of claim 5, further comprising following steps:
forming a cathode on a side of the electron injection layer away from the anode by vapor deposition.

7. The manufacturing method of claim 1, wherein a material of the anode comprises any one of a nano-gold, a nano-silver, or a carbon electrode.

8. The manufacturing method of claim 1, wherein a material of the perovskite quantum dot light-emitting layer comprises any one of an organic-inorganic-hybridized perovskite material or an inorganic perovskite material.

9. The manufacturing method of claim 1, wherein the perovskite quantum dot light-emitting layer comprises any one of a red perovskite quantum dot light-emitting layer, a green perovskite quantum dot light-emitting layer, or a blue perovskite quantum dot light-emitting layer.

10. The manufacturing method of claim 9, wherein the pixel opening comprises a red sub-pixel opening, a green sub-pixel opening, and a blue sub-pixel opening;
the perovskite quantum dot light-emitting layer in the red sub-pixel opening is the red perovskite quantum dot light-emitting layer, the perovskite quantum dot light-emitting layer in the green sub-pixel opening is the green perovskite quantum dot light-emitting layer, and the perovskite quantum dot light-emitting layer in the blue sub-pixel opening is the blue perovskite quantum dot light-emitting layer.

11. The manufacturing method of claim 1, wherein a material of the flexible substrate comprises any one or more of polyimide, polypropylene, and polyvinyl chloride.

12. The manufacturing method of claim 1, wherein a material of the pixel barrier wall comprises a black color resist material.

13. A manufacturing method of a flexible display panel, comprising following steps:
providing a flexible substrate;
forming a pixel barrier wall on the flexible substrate, wherein the pixel barrier wall is formed around a pixel opening;
forming an anode, a hole injection layer, a hole transport layer, a perovskite quantum dot light-emitting layer, an electron transport layer, and an electron injection layer successively in the pixel opening by inkjet printing; and
forming a cathode on a side of the electron injection layer away from the anode by vapor deposition.

14. The manufacturing method of claim 13, wherein forming the pixel barrier wall on the flexible substrate comprises following steps:
covering a photoresist layer on the flexible substrate; and
patterning the photoresist layer to form the pixel barrier wall.

15. The manufacturing method of claim 13, wherein a material of the anode comprises any one of a nano-gold, a nano-silver, or a carbon electrode.

16. The manufacturing method of claim 13, wherein a material of the perovskite quantum dot light-emitting layer comprises any one of an organic-inorganic-hybridized perovskite material or an inorganic perovskite material.

17. The manufacturing method of claim 13, wherein the perovskite quantum dot light-emitting layer comprises any one of a red perovskite quantum dot light-emitting layer, a green perovskite quantum dot light-emitting layer, or a blue perovskite quantum dot light-emitting layer.

18. The manufacturing method of claim 17, wherein the pixel opening comprises a red sub-pixel opening, a green sub-pixel opening, and a blue sub-pixel opening;
the perovskite quantum dot light-emitting layer in the red sub-pixel opening is the red perovskite quantum dot light-emitting layer, the perovskite quantum dot light-emitting layer in the green sub-pixel opening is the green perovskite quantum dot light-emitting layer, and the perovskite quantum dot light-emitting layer in the blue sub-pixel opening is the blue perovskite quantum dot light-emitting layer.

19. The manufacturing method of claim 13, wherein a material of the flexible substrate comprises any one or more of polyimide, polypropylene, and polyvinyl chloride.

20. The manufacturing method of claim 13, wherein a material of the pixel barrier wall comprises a black color resist material.
